(19) United States
(12) Patent Application Publication
(10) Pub. No.: US 2004/0183070 A1
(43) Pub. Date: Sep. 23, 2004

(54) Solution processed pentacene-acceptor heterojunctions in diodes, photodiodes, and photovoltaic cells and method of making same

(75) Inventors: Ali Afzali-Ardakani, Yorktown Heights, NY (US); Cherie R. Kagan, Ossining, NY (US); Christopher B. Murray, Ossining, NY (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY

(21) Appl. No.: 10/392,985

(22) Filed: Mar. 21, 2003

(51) Int. Cl. H01L 35/24; H01L 51/00

(52) U.S. Cl. 257/40

(57) ABSTRACT

An organic semiconductor device is formed on a substrate by solution deposition of an active channel layer interposed between a pair of electrodes. The active channel layer includes pentacene formed by thermal treatment of its precursors and operates as a hole carrier. Within the pentacene film are nanoparticles or nanowires of a second material that operate as electron carriers. The electron carrier materials are selected from a group of soluble semiconducting inorganic nanocrystals and nanowires or solube derivatives of fullerene.

### BACKGROUND OF THE INVENTION

1. Field of the Invention

The present invention generally relates to the fabrication of heterojunctions from interpenetrating mixtures of soluble pentacene precursors, which subsequently form pentacene as a hole-carrier, and soluble or dispersible semiconducting materials, which act as electron carriers. More particularly, this invention relates to the use of such heterojunctions in diodes, photodiodes, and photovoltaic cells.

2. Description of the Related Art

Solid state heterojunctions, such as, the pn junction between p-type and n-type semiconductors, have found widespread application in modern electronics. Such pn junctions typically exhibit diode rectification and are, therefore, useful in a wide variety of electronic circuit applications. The pn heterojunction is useful as a single electronic device, such as, a diode, and often is part of more complex electronic circuits including transistors, which have more than one pn heterojunction.

A principle feature of the pn heterojunction is the built-in potential barrier at the interface between the p-type semiconductor, that is, a donor material, and the n-type semiconductor, that is, an acceptor material. This built-in potential barrier arises fundamentally from the difference in electronegativities of the two materials that make up the heterojunction. The built-in potential barrier and the associated difference in electronegativities of the heterojunction materials give rise to the origin of the rectifying nature of the device.

When electrons, that is, negative electrical charges, and holes, that is, positive electrical charges, are generated by photons in the vicinity of the heterojunction, the built-in potential barrier and the associated difference in electronegativities help to separate the negative and positive electrical charges. This electrical charge separation at the heterojunction provides the photovoltaic effect. Such pn heterojunctions, functioning as diodes, can serve as photodiodes, or the pn heterojunctions can form the fundamental elements of a photovoltaic cell, more commonly known as a solar cell.

Solar cells are large-area pn junction photodiodes, which are optimized to convert light to electrical power. Currently, solar cells are fabricated from conventional inorganic semiconductor materials, for example, silicon, gallium arsenide, cadmium sulfide, copper indium diselenide, etc. Since fabrication techniques using these inorganic semiconductor materials require costly, high-vacuum processing and in many cases, high-temperature processing, solar cells fabricated from these materials have limited use.

For the above reasons, there has been considerable interest for many years in the development of organic p-type and n-type semiconductor materials for pn junctions for electronic device applications. Recent developments within the art disclose the use of interpenetrating blends of organic materials as p-type and/or n-type semiconductor materials for the fabrication of pn heterojunction and devices incorporating such pn heterojunctions.

Among organic pn heterojunctions, composites of conjugated polymers, in which p-type semiconductors act as donor materials, and functional fullerenes, in which n-type semiconductors act as acceptor materials, have emerged as promising materials for photovoltaic cells. Solar cells, having a power efficiency of up to 3%, have been demonstrated with blends of fullerenes and conjugated polymers.

More recent examples of organic pn heterojunctions include the combination of inorganic nanocrystalline semiconductors, known as quantum dots, and conjugated organic polymers. In this example, light may be absorbed by both the quantum dots, whose absorption spectrum may be tailored by quantum dot size and composition, and the conjugated organic polymer. At low concentrations of quantum dots, the electrical charge carriers are separated and the positively charged holes are transported through the polymer matrix and collected. At high concentrations, sufficient to achieve percolation, the negatively charged electrons may tunnel through the quantum dots, so that, both the electrons and the holes, traveling through the inorganic and organic components, respectively, may be collected at the electrodes. To increase the rate of electrical charge transport between inorganic nanocrystals, recent efforts have included using nanorods. However, the polymeric organic semiconductors used have low carrier mobilities, and therefore, short carrier lifetimes, limiting the collection efficiency of photovoltaic devices.

In order to make solar cells based on organic materials commercially viable, the power efficiency of the photovoltaic cells must be increased. One factor, which is paramount in determining the photovoltaic activity of the organic compounds, is their absorption spectra. In solar cells, the absorbed photons from the sun are converted into electrical current. Therefore, ideally both p-type and n-type materials should have absorption spectra in the visible and near infra red regions of the solar spectrum to capture the maximum photon flux.

Once the photon is absorbed, the exciton must be separated to form free electrons and free holes by overcoming their binding energy. In photovoltaic devices, charge carriers are separated at the interface between the p-type and n-type semiconductors. Increasing the interfacial area when using composite materials, such as organic and inorganic composites, increases the generation of free carriers.

Another factor, which is as important as the absorption spectra and the pn interface, is the mobility of the free holes for the p-type material and of the free electrons for the n-type material, which together form the pn junction. Conjugated organic polymeric materials, for example, poly(3-alkylthiophene) and poly(para-phenylenevinylene), which have been used as p-type materials for solar cells, have relatively, very low charge carrier mobilities, that is, 10 ⁻⁴ to 10⁻² cm² ·V⁻¹·s⁻¹. The higher the charge carrier mobility, the lower the loss to carrier recombination that may limit photocarrier collection.

Among the organic semiconductor materials, pentacene shows the highest charge carrier mobility. In fact, the charge carrier mobility of pentacene is comparable to that of amorphous silicon. However, pentacene is insoluble in common organic solvents, and thus, can not be used to form composites with n-type semiconductors by low-cost solution-based processes, necessary for the commercial viability of photovoltaic devices.

### SUMMARY OF THE INVENTION

In view of the foregoing and other problems and disadvantages of conventional techniques, it is an advantage of the present invention to fabricate an interpenetrating composite having pn heterojunctions, which include pentacene as the p-type component.

It is another advantage of the present invention to form the interpenetrating composite through the use of soluble pentacene precursors.

Yet another advantage of this invention is to fabricate photovoltaic cells comprising interpenetrating composites of pentacene with soluble n-type organic materials.

Still another advantage of this invention is to form a pn heterojunction comprising pentacene, as the p-type component, with soluble fullerenes or nanotubes, or soluble or dispersible inorganic semiconducting nanocrystals or nanowires as the n-type component.

In a first aspect of the present invention a fabrication of a pn heterojunction is provided, using a soluble precursor of pentacene, which subsequently forms pentacene as a p-type material acting as a hole carrier, and fullerenes, nanotubes, or inorganic semiconducting nanocrystals or nanowires as an n-type semiconducting material acting as an electron carrier. The present invention may utilize the processing advantages associated with soluble pentacene precursors, and soluble fullerenes or nanotubes, or soluble or dispersible inorganic semiconducting nanocrystals or nanowires to fabricate electronic devices having a large active area.

The present invention may also include compositions useful as photovoltaic cells, which are fabricated from composites of a soluble pentacene precursor, which subsequently forms pentacene as a p-type material acting as a hole carrier, and fullerenes or nanotubes, or soluble or dispersible inorganic semiconducting nanocrystals or nanowires as an n-type semiconducting material acting as an electron carrier.

Another aspect of the present invention is to provide a high efficiency composite material for photovoltaics that may be deposited by solution processing at a low-cost, a low-temperature, and by conformal techniques over large areas for low-cost, flexible applications.

The present invention may also provide charge carrier separation for use in molecular information storage and/or optoelectronics. In this aspect of the present invention, donor-acceptor pairs may serve as bistable ‘molecular storage units’, in which, a separated ion-radical pair corresponds to one state, with a ground state corresponding to the second state. Heterojunction solar cells, using this charge separation, have been demonstrated with devices using a soluble pentacene precursor and nanocrystals.

The present invention may not require high-temperature or costly, high-vacuum processes because the soluble pentacene precursor, and the soluble fullerene derivatives or soluble or dispersible inorganic semiconducting nanocrystals or nanowires are amenable to fabrication processes using solution processing. This significantly simplifies the fabrication process, especially for large active area, and enables a wide range of substrate materials, including glasses, ceramics, plastics, and sapphire to be used.

The present invention may also show a greater percentage of absorbed solar energy that generates photoexcitations, which may then be separated into free charge carriers and collected. Pentacene has a lower band gap energy than most conjugated polymers; thus, allowing absorption over a good portion of the visible spectrum. In the present invention, the inorganic nanocrystals or nanowires may have an increased density of states for absorption beyond the band-edge, which may give rise to a broad and large absorption that increases the spectral sensitivity of the pentacene-nanocrystal or pentacene-nanowire composite. The optical density may be further increased in nanocrystalline materials by the confinement of excitations to the reduced dimensionality of the nanoscale material, when compared to bulk semiconductors.

In the present invention, the modulation of the energy spectrum between pentacene and either fullerenes, or inorganic nanocrystals or nanowires may form a type-II heterojunction that provides a driving force to increase electrical charge separation of absorbed photons in the visible to near infrared regions of the solar spectrum, which may in turn lead to increased power efficiency.

In the present invention, the large interfacial area between pentacene and the fullerenes, nanotubes, or the inorganic nano-scale quantum dots or quantum wires, may also provide increased electrical charge separation, which leads to increased power efficiency. In the present invention, the high hole mobility of pentacene, in contrast to other conjugated organic materials, reduces the recombination loss of carriers, which may lead to a higher power efficiency.

In order to attain the above and other advantages and aspects, according to an exemplary embodiment of the present invention, disclosed herein is a heterojunction that comprises pentacene as a hole-carrying material, and a semiconducting material as an electron-carrying material, in which the pentacene and the semiconducting material form the heterojunction.

In another exemplary embodiment of the present invention, a photoelectric device comprises a substrate, a photoactive channel layer, the photoactive channel layer comprising the heterojunction, and two electrodes, the photoactive channel layer being interposed between the two electrodes.

In another exemplary embodiment of the present invention, the electron-carrying material is selected from the group comprising semiconducting nanocrystals, semiconducting nanowires, nanotubes, and Buckminsterfullerenes.

In another exemplary embodiment of the present invention, a method of making a photoelectric device that includes heterojunctions is described, in which the method comprises mixing a soluble precursor of pentacene and a soluble or dispersible semiconducting material in an organic solvent to obtain a mixture, depositing the mixture as a film on a substrate, and heating the film deposited on the substrate to obtain the heterojunctions between the pentacene and the semiconducting material.

In another exemplary embodiment of the present invention, heating results in thermal conversion of the soluble precursor of pentacene to the pentacene.

In another exemplary embodiment of the present invention, the soluble precursor of pentacene is represented by a formula:

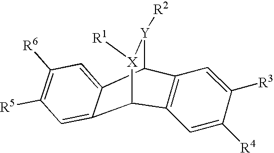

in which each X and Y is selected from the group comprising N, O, S, SO, and SO₂, each R and R² is selected from the group comprising hydrogen, alkyls of 1-12 carbon atoms, aryls, substituted aryls, aralkyls, alkoxycarbonyls, aryloxycarbonyls, and acyls, and each R³, R⁴, R⁵, and R⁶ is selected from the group comprising alkyls of 1-12 carbon atoms, alkoxys, acyls, aryls, aralkyls, chloroalkyls, fluoroalkyls, and substituted aryls having a substituent selected from —F, —Cl, —Br, —NO₂, —CO₂R, —PO₃H, —SO₃H, trialkylsilyl, and acyl, with the proviso that at least one of X and Y is a hetero-atom selected from the group comprising N, O, and S.

In another exemplary embodiment of the present invention, the method of making a photoelectric device that includes heterojunctions further comprises forming an electrode on a portion of an upper surface of the film.

In another exemplary embodiment of the present invention, the substrate is a conducting layer, which forms an electrode.

In another exemplary embodiment of the present invention, a semiconductor device, which includes pn heterojunctions, comprises a conducting layer disposed on a substrate, a thin film disposed on the conducting layer, where the thin film comprises pentacene, as a p-type hole-carrying material, and a semiconducting material, as an n-type electron-carrying material, in which the pentacene and the semiconducting material comprise an interpenetrating mixture.

In another exemplary embodiment of the present invention, the semiconducting material is selected from the group comprising cadmium selenide, cadmium sulfide, cadmium telluride, lead selenide, lead sulfide, lead telluride, indium phosphide, and silicon.

In another exemplary embodiment of the present invention, the semiconducting material comprises nanocrystals or nanowires.

In another exemplary embodiment of the present invention, the nanocrystals or nanowires are coated with an organic monolayer to enhance solubility.

In another exemplary embodiment of the present invention, the semiconducting material comprises chemically-substituted Buckminsterfullerenes or coated nanotubes, which are soluble in organic solvents.

In another exemplary embodiment of the present invention, the semiconductor device further comprises an electrode formed on an upper surface of the thin film.

In another exemplary embodiment of the present invention, the thin film absorbs light in the visible region of the spectrum.

In another exemplary embodiment of the present invention, the thin film absorbs light in the near infrared region of the spectrum.

In another exemplary embodiment of the present invention, the semiconductor device comprises a photo diode.

In another exemplary embodiment of the present invention, the semiconductor device comprises a photovoltaic cell.

In another exemplary embodiment of the present invention, the substrate comprises at least one of glass, ceramic, plastic, and sapphire.

In another exemplary embodiment of the present invention, the conducting layer comprises an indium tin oxide layer, which is transparent.

In another exemplary embodiment of the present invention, the conducting layer comprises a conducting polymer layer, which is transparent.

Thus, the present invention may fabricate photoelectronic devices, which are fabricated from composites of a soluble pentacene precursor that subsequently forms pentacene as a p-type material acting as a hole carrier, and fullerenes or nanotubes, or soluble or dispersible inorganic semiconducting nanocrystals or nanowires as an n-type semiconducting material acting as an electron carrier by solution processing at a low-cost, a low-temperature, and by conformal techniques over large areas for low-cost, flexible applications.

### BRIEF DESCRIPTION OF THE DRAWINGS

The foregoing and other aspects of the present invention will be better understood from the following detailed description of preferred embodiments of the present invention with reference to the figures, in which:

FIG. 1 illustrates the ultraviolet (UV) and visible spectrum of a pentacene precursor and of pentacene in an exemplary embodiment of the present invention;

FIG. 2 illustrates the visible and near infrared (IR) spectrum of lead selenide nanocrystals in an exemplary embodiment of the present invention;

FIG. 3(a) illustrates a current versus voltage characteristic of a pentacene-lead selenide (PbSe) nanocrystal composite in the dark and when illuminated with 420 nm light, and FIG. 3(b) illustrates the photoconductivity of the pentacene-(PbSe) nanocrystal composite versus the wavelength of excitation in an exemplary embodiment of the present invention;

FIG. 4(a) illustrates a photoelectronic device in which an active layer 120 is sandwiched by a conducting layer 110 and an electrode 130 in an exemplary embodiment of the present invention;

FIG. 4(b) illustrates a photoelectronic device in which an active layer 120 is deposited on a substrate 100 and a pair of electrodes 131, 132 are subsequently formed on the active layer 120 in an exemplary embodiment of the present invention;

FIG. 4(c) illustrates a photoelectronic device in which a pair of electrodes 131, 132 are formed on a substrate 100 and an active layer 120 is subsequently deposited over the pair of electrodes 131, 132 and the substrate 100 in an exemplary embodiment of the present invention; and

FIG. 5 illustrates a flowchart of a method 500 of fabricating a photovoltaic or photoemissive device using a pentacene precursor and a soluble or dispersible fullerene or nanotube, or inorganic semiconducting nanocrystal or nanowire in an exemplary embodiment of the present invention.

### DETAILED DESCRIPTION OF PREFERRED EMBODIMENTS OF THE INVENTION

The present invention generally describes the use of a soluble precursor of pentacene to form the p-type component, that is, the hole carrier, of a pn heterojunction.

Pentacene, used as the p-type component of the present invention, may be formed by thermal conversion of a soluble pentacene precursor. The choice of pentacene, as the p-type component of the pn heterojunction, is due to its high carrier mobility of holes, when compared to other organic semiconductor materials. Furthermore, because pentacene has a lower band gap energy than most organic polymeric materials used as p-type components, the pentacene pn heterojunction absorbs a wider range of the solar spectrum.

Pentacene is insoluble in most common organic solvents and in order to form a pn junction composite by solution deposition, a soluble pentacene precursor may be used, which after deposition as a thin film, may be converted to pentacene by heating. Soluble precursors of pentacene have been reported recently by A. Afzali et al., “High Performance, Solution-Processed Organic Thin Film Transistors from a Novel Pentacene Precursor,” J. Am. Chem. Soc., 2002, 124, 8812-8813, and A. Afzali et al., U.S. patent application Ser. No. 10/323,899, commonly assigned to the present assignee, and both incorporate herein by reference. These precursor adducts are soluble in commonly used organic solvents, and after deposition as thin films, the precursor adducts may be converted to pentacene by heating at moderate temperatures, for example, about 120° C. to about 200° C., as shown in the following scheme, where adduct 1 is converted to pentacene 2 by heating.

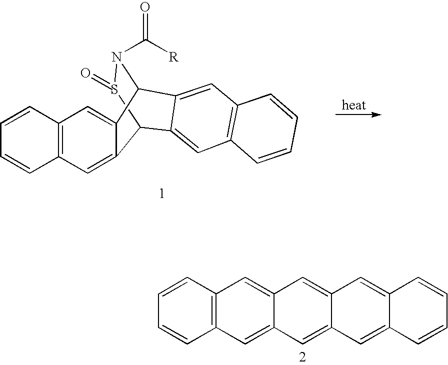

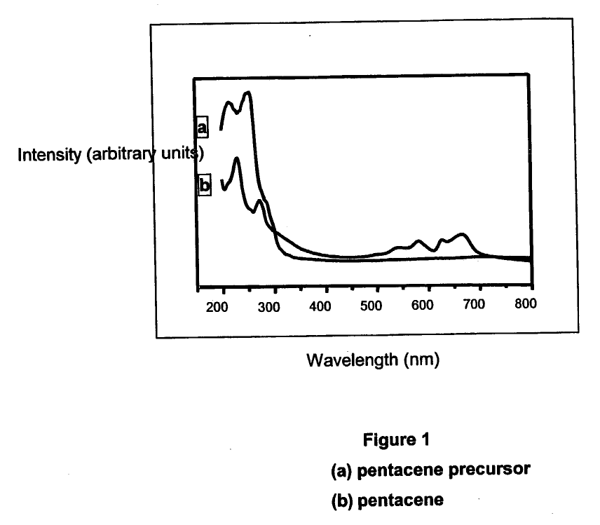

Compound 1 is an example of a soluble precursor of pentacene, in this case, a Diels-Alder adduct of pentacene and N-sulfinylamide, which may be deposited from solution to form a thin film that is subsequently converted to pentacene. FIG. 1 illustrates the ultraviolet (UV) and visible spectrum of a pentacene precursor and of pentacene in an exemplary embodiment of the present invention.

As for a soluble or dispersible n-type component of the pn heterojunction of an exemplary embodiment of the present invention, there are two classes of n-type compounds that may be used.

The first class comprises derivatives of Buckminsterfullerenes or carbon nanotubes, which have received considerable attention in recent years. Fullerenes, including C₆₀, are excellent electron acceptors capable of accepting as many as six electrons as is well known in the art. C₆₀, therefore, may form charge transfer salts with a variety of strong electron donors. The fullerenes have been expanded into a growing class of structures, including, for example, distorted bucky balls, for example, C₇₀, chemically-substituted bucky balls, bucky tubes, etc. Among these, chemically-substituted bucky balls may be soluble in common organic solvents, and thus, used in an exemplary embodiment of the present invention. Although carbon nanotubes are not soluble, recent efforts to coat the nanotubes in a polymer or single stranded DNA have resulted in soluble nanotubes.

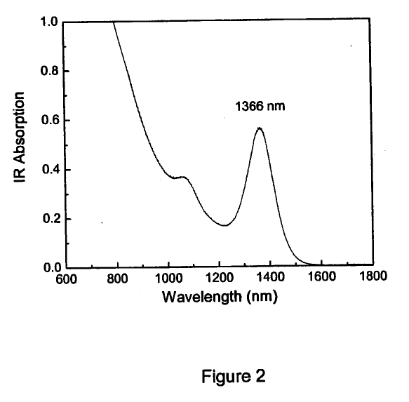

The second class of compounds, which may be used in an exemplary embodiment of the present invention, are soluble or dispersible inorganic nanocrystals or nanowires, such as, for example, cadmium selenide, cadmium sulfide, cadmium telluride, lead selenide, lead sulfide, lead telluride, indium phosphide, silicon, etc. Nanocrystals, also known as quantum dots, which have dimensions of 1-20 nm, have been studied for their finite size effects that result in novel electronic, magnetic, and optical properties. Nanocrystals of a variety of metals and semiconductors that are coated by organic monolayers, for example, long chain alkane phosphonic acids and trialkyl phosphines, have been synthesized to provide greater solubility within organic solvents and to provide greater stability. FIG. 2 illustrates the visible and near infrared (IR) spectrum of lead selenide nanocrystals in an exemplary embodiment of the present invention.

Soluble precursors of pentacene that may be converted to pentacene by heating at, for example, about 120° C. to about 200° C., may be generalized by the following structure,

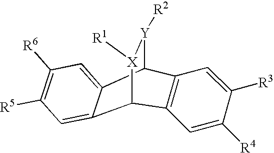

where each X and Y may be independently selected from N, O, S, SO, and SO₂, each R¹ and R² may be independently selected from hydrogen, alkyls of 1-12 carbon atoms, aryls, substituted aryls, aralkyls, alkoxycarbonyls, aryloxycarbonyls, and acyls, and each R³, R⁴, R⁵, and R⁶ may be independently selected from the group of alkyls of 1-12 carbon atoms, alkoxys, acyls, aryls, aralkyls, chloroalkyls, fluoroalkyls, and substituted aryls having a substituent selected from —F, —Cl, —Br, —NO₂, —CO₂R, —PO₃H, —SO₃H, trialkylsilyl, and acyl, with the proviso that at least one of X and Y may be a hetero-atom selected from N, O, and S.

In various exemplary embodiments, these specific adducts may be represented by compounds 3-10, shown below.

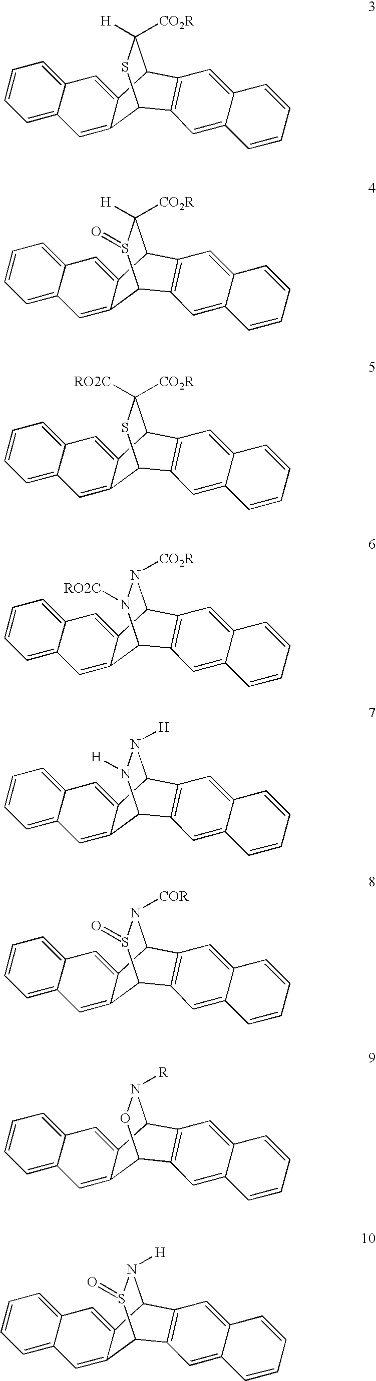

The n-type component of the pn heterojunctions of an exemplary embodiment of the present invention may be selected from either chemically-substituted C₆₀ compounds or nanotubes, which may be soluble in organic solvents, or from soluble or dispersible inorganic semiconducting nanocrystals or nanowires, represented by, for example, cadmium selenide, cadmium sulfide, cadmium telluride, lead selenide, lead sulfide, lead telluride, indium phosphide, silicon etc. These inorganic nanocrystals or nanowires may have dimensions ranging from about 1 to about 20 nm and may be surrounded by a monolayer of an organic compound to impart stability and solubility and to control the electronic properties of the nanocrystal or nanowire surface.

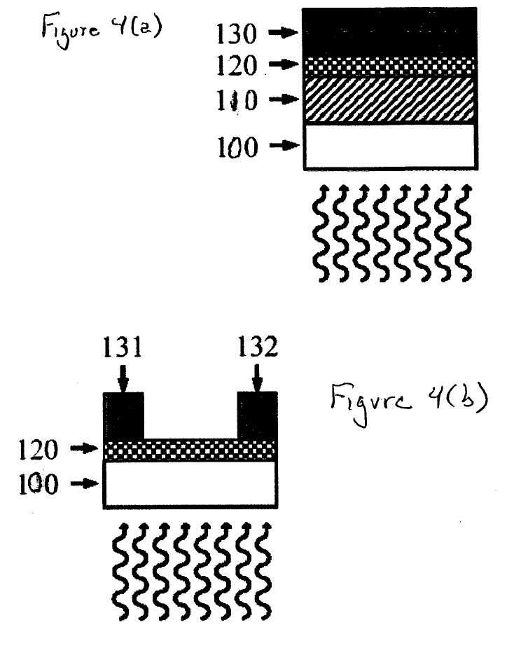

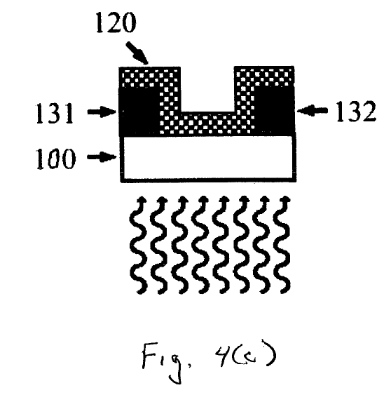

As illustrated in FIG. 4(a), in an exemplary embodiment of the present invention, a photoelectronic device may be fabricated by solution processing. A transparent conducting layer 110, such as, but not limited to indium-tin oxide (ITO), acting as a first electrode, may be coated on a substrate 100, which may be selected from glasses, ceramics, plastics, sapphire, and other materials well known in the art.

A portion of the transparent conducting layer 110 may then be coated by solution deposition of a mixture of pentacene precursors, for example, compounds 1 and 3-10 illustrated above, and an n-type material, such as, for example, soluble fullerenes or nanotubes, or soluble or dispersible inorganic semiconducting nanocrystals or nanowires, to form an active layer 120. The mixture of pentacene precursors and an n-type material is thoroughly mixed in an organic solvent, such that, there exists no significant agglomeration of either the pentacene precursor or the n-type material; thus, forming an interpenetrating mixture of these two components.

The substrate may then be heated at a moderate temperature, for example, about 120° C. to about 200° C., to convert the pentacene precursor of the active layer 120 to pentacene. In various exemplary embodiments, a second electrode 130 may be formed on at least a portion of the active layer 120.

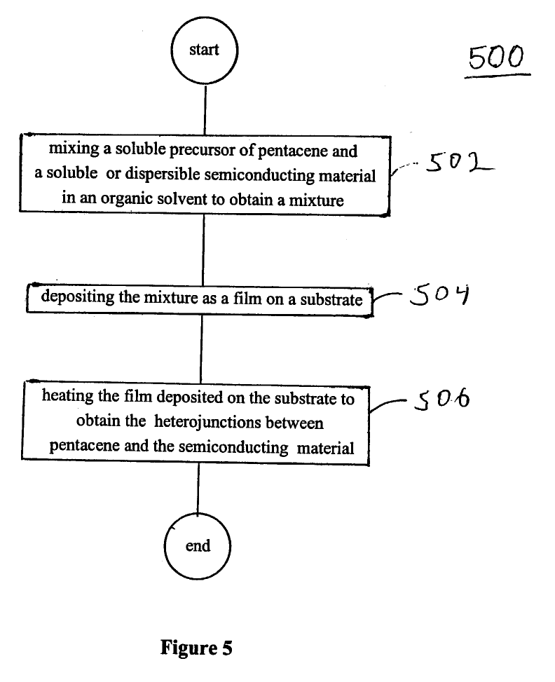

FIG. 5 illustrates this method of fabrication by a flowchart 500 including mixing a soluble precursor of pentacene and a soluble or dispersible semiconducting material in an organic solvent to obtain a mixture 502, depositing the mixture as a film on a substrate 504, and heating the film deposited on the substrate to obtain the heterojunction between pentacene and the semiconducting material 506. The mixture of a soluble pentacene precursor and a soluble or dispersible n-type material is thoroughly mixed in an organic solvent, such that, there exists no significant agglomeration of either the pentacene precursor or the n-type material; thus, forming an interpenetrating mixture of these two components.

In various exemplary embodiments, a photoelectronic device may also be fabricated, as illustrated in FIG. 4(b).

In such a fabrication, first, an active layer 120, is deposited as a thin film of a mixture of a pentacene precursor and a soluble acceptor, which is selected from soluble chemically-substituted fullerenes or soluble nanotubes, and soluble or dispersible inorganic semiconducting nanocrystals or nanowires to form an interpenetrating mixture of the two components, may be coated on a substrate 100. The substrate 100 may be selected from glasses, ceramics, plastics, sapphire, or other materials well known in the art.

Then, two electrodes 131 and 132 may then be deposited by conventional photolithography or stencil techniques on the active layer 120. The substrate may then be heated at moderate temperatures, for example, about 120° C. to about 200° C., to convert the pentacene precursor of the thin film mixture of active layer 120 to pentacene.

In various exemplary embodiments, a photoelectronic device may also be fabricated, as illustrated in FIG. 4(c).

In such a fabrication, first, two electrodes 131 and 132 are deposited by conventional photolithography or stencil mask techniques on a substrate 100. The substrate 100 may be selected from glasses, ceramics, plastics, sapphire, or other materials well known in the art.

Then, an active layer 120, deposited as a thin film of a mixture of a pentacene precursor and a soluble acceptor, which is selected from soluble chemically-substituted fullerenes or soluble nanotubes, and soluble or dispersible inorganic semiconducting nanocrystals or nanowires to form an interpenetrating mixture of the two components, may be coated on a substrate 100 patterned with two electrodes 131 and 132. The substrate may then be heated at moderate temperatures, for example, about 120° C. to about 200° C., to convert the pentacene precursor of the thin film mixture of active layer 120 to pentacene.

### EXPERIMENTAL EXAMPLES

As shown in FIG. 4(c), a pair of gold electrodes 131, 132 was formed on a sapphire substrate 100. A solution of lead selenide nanocrystals with a diameter of about 3.8 nm, that is, approximately 100 mg, and a pentacene adduct of pentacene and N-sulfinylacetamide, as shown in 1, above, where R═CH₃, of approximately 25 mg in chloroform, was then coated on the sapphire substrate 100 and the pair of gold electrodes 131, 132. The substrate 100 was then heated at approximately 150° C. for approximately 5 minutes to convert the pentacene adduct 1 to pentacene within the mixture of the active layer 120.

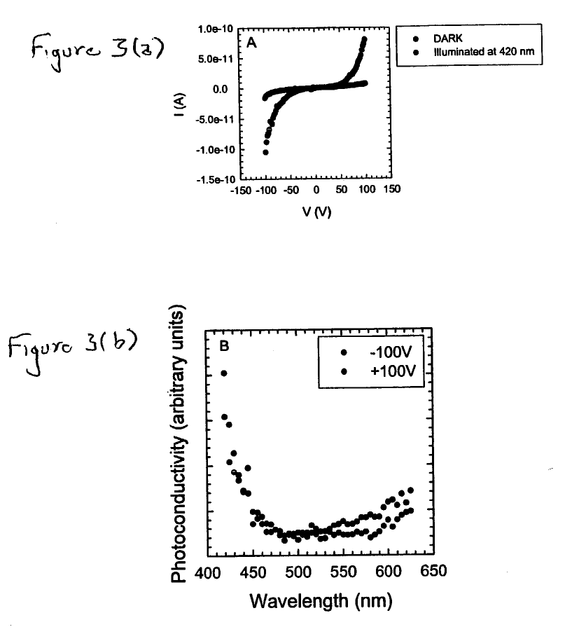

FIG. 3(a) shows a photoelectric current measured on an experimental photoelectronic device corresponding to the exemplary embodiment of FIG. 4(c) above. The photoelectronic device was fabricated from a mixture of a pentacene precursor and lead selenide nanocrystals, about 3.8 nm in diameter, that was spin-coated onto a sapphire substrate prepared with a pair of gold electrodes, as described above. The pair of electrodes had a distance of separation of approximately 10 μm. After removal of the organic solvent, the substrate was heated under nitrogen at approximately 150° C. for approximately 10 minutes to convert the pentacene precursor to pentacene. Various voltages were applied across the two gold electrodes and the current passing between the electrodes was measured in the dark and while illuminated with light of 420 nm.

FIG. 3(b) illustrates the photoconductivity of the photoelectronic device exemplified by FIG. 4(c), above, as a function of wavelength of illumination. A 150 W xenon (Xe) lamp was focused on the entrance slits of a monochronometer to select the wavelength of light emanating from the exit slits. The light was then imaged onto the active area of the photoelectronic device and the current-voltage (I-V) characteristics were determined by applying voltages to the electrodes and measuring the resulting current between the electrodes, as the wavelength of the applied light was changed by moving the grating of the monochronometer. The relative light intensity at each wavelength was also measured with a power meter to normalize for the variation in lamp intensity with wavelength.

It is another advantage of the present invention to form the interpenetrating composite through the use of soluble pentacene precursors.

Yet another advantage of this invention is to fabricate photovoltaic cells comprising interpenetrating composites of pentacene with soluble n-type organic materials.

Still another advantage of this invention is to form a pn heterojunction comprising pentacene, as the p-type component, with soluble fullerenes or nanotubes, or soluble or dispersible inorganic semiconducting nanocrystals or nanowires as the n-type component.

While the invention has been described in terms of exemplary embodiments, those skilled in the art will recognize that the invention can be practiced with modifications within the spirit and scope of the appended claims.

Further, it is noted that Applicants' intent is to encompass equivalents of all claim elements, even if amended later during prosecution.

We claim:

1. A heterojunction, comprising:
pentacene as a hole-carrying material; and
a semiconducting material as an electron-carrying material, the pentacene and the semiconducting material being in juxtaposition

2. A photoelectric device, comprising:
a substrate;
a photoactive channel layer, the photoactive channel layer comprising the heterojunction of claim 1; and
two electrodes, the photoactive channel layer being interposed between the two electrodes.

3. The photoelectric device of claim 2, wherein the electron-carrying material comprises at least one of semiconducting nanocrystals, semiconducting nanowires, nanotubes, and Buckminsterfullerenes.

4. A method of making a photoelectric device that includes a heterojunction, the method, comprising:
mixing a soluble precursor of pentacene and a soluble or dispersible semiconducting material in an organic solvent to obtain a mixture;
depositing the mixture as a film on a substrate; and
heating the film deposited on the substrate to obtain the heterojunction between the pentacene and the semiconducting material.

5. The method of claim 4, wherein heating results in thermal conversion of the soluble precursor of pentacene to the pentacene.

6. The method of claim 4, wherein the soluble precursor of pentacene is represented by a formula: 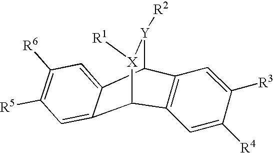
wherein each X and Y comprises at least one of N, O, S, SO, and SO₂, each R¹ and R² comprises at least one of hydrogen, alkyls of 1-12 carbon atoms, aryls, substituted aryls, aralkyls, alkoxycarbonyls, aryloxycarbonyls, and acyls, and each R³, R⁴, R⁵, and R⁶ comprises at least one of alkyls of 1-12 carbon atoms, alkoxys, acyls, aryls, aralkyls, chloroalkyls, fluoroalkyls, and substituted aryls having a substituent selected from —F, —Cl, —Br, —NO₂, —CO₂R, —PO₃H, —SO₃H, trialkylsilyl, and acyl, with the proviso that at least one of X and Y comprises a hetero-atom including at least one of N, O, and S.

7. The method of claim 6, further comprising forming an electrode on a portion of an upper surface of the film.

8. The method of claim 6, wherein the substrate comprises a conducting layer, which forms an electrode.

9. A semiconductor device that includes a pn heterojunction, the semiconductor device, comprising:
a conducting layer disposed on a substrate;
a thin film disposed on the conducting layer, the thin film, comprising:
pentacene, as a p-type hole-carrying material; and
a semiconducting material, as an n-type electron-carrying material,
wherein the pentacene and the semiconducting material comprise an interpenetrating mixture.

10. The semiconductor device of claim 9, wherein the semiconducting material comprises at least one of cadmium selenide, cadmium sulfide, cadmium telluride, lead selenide, lead sulfide, lead telluride, indium phosphide, and silicon.

11. The semiconductor device of claim 9, wherein the semiconducting material comprises nanocrystals or nanowires.

12. The semiconductor device of claim 11, wherein the nanocrystals or nanowires are coated with an organic monolayer.

13. The semiconductor device of claim 9, wherein the semiconducting material comprises chemically-substituted Buckminsterfullerenes or coated nanotubes, which are soluble in organic solvents.

14. The semiconductor device of claim 9, further comprising an electrode formed on an upper surface of the thin film.

15. The semiconductor device of claim 9, wherein the thin film absorbs light in a visible region of the spectrum.

16. The semiconductor device of claim 9, wherein the thin film absorbs light in a near infrared region of the spectrum.

17. A photodiode comprising the semiconductor device of claim 9.

18. A photovoltaic cell comprising the semiconductor device of claim 9.

19. The semiconductor device of claim 9, wherein the substrate comprises at least one of glass, ceramic, plastic, and sapphire.

20. The semiconductor device of claim 9, wherein the conducting layer comprises an indium tin oxide layer, which is transparent.

21. The semiconductor device of claim 9, wherein the conducting layer comprises a conducting polymer layer, which is transparent.
